(19) United States
(12) Patent Application Publication
(10) Pub. No.: US 2025/0246567 A1
(43) Pub. Date: Jul. 31, 2025

(54) CHIP PACKAGE STRUCTURE AND METHOD FOR FORMING THE SAME

(71) Applicant: Taiwan Semiconductor Manufacturing Company, Ltd., Hsinchu (TW)

(72) Inventors: Jui-Shen CHANG, Taichung City (TW); Tien-Chung YANG, Hsinchu City (TW); Jyun-Yang WANG, Hsinchu City (TW); Chen-Nan CHIU, Hsinchu City (TW); Yao-Chun CHUANG, Hsinchu City (TW)

(73) Assignee: Taiwan Semiconductor Manufacturing Company, Ltd., Hsinchu (TW)

(21) Appl. No.: 18/426,796

(22) Filed: Jan. 30, 2024

(51) Int. Cl. H01L 23/00

(52) U.S. Cl. CPC H01L 24/08; H01L 24/05; H01L 24/80; H01L 2224/05647; H01L 2224/05649; H01L 2224/05657; H01L 2224/05666; H01L 2224/05681; H01L 2224/08145; H01L 2224/80895; H01L 2224/80896

(57) ABSTRACT

A method for forming a chip package structure is provided. The method includes providing a first wiring substrate including a first dielectric layer and a first bonding pad embedded in the first dielectric layer. The method includes providing a second wiring substrate over the first wiring substrate, wherein the second wiring substrate includes a second dielectric layer and a second bonding pad embedded in the second dielectric layer, and the second bonding pad is over the first bonding pad. The method includes performing an annealing process to bond the second bonding pad to the first bonding pad, wherein a metal oxide layer is formed between the seed layer and the first dielectric layer after the annealing process, and the metal oxide layer includes the first metal element and the third metal element.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1B are cross-sectional views of various stages of a process for forming a semiconductor structure, in accordance with some embodiments.

FIGS. 2A-2E are enlarged cross-sectional views of various stages of a process for forming the bonding pad and the conductive via structure of the semiconductor structure of FIG. 1B, in accordance with some embodiments.

FIG. 2B-1 is an enlarged cross-sectional view of a portion of the semiconductor structure of FIG. 2B, in accordance with some embodiments.

FIGS. 3A-3B are cross-sectional views of various stages of a process for forming a semiconductor structure, in accordance with some embodiments.

FIGS. 4A-4E are enlarged cross-sectional views of various stages of a process for forming the bonding pad and the conductive via structure of FIG. 3B, in accordance with some embodiments.

FIG. 4B-1 is an enlarged cross-sectional view of a portion of the semiconductor structure of FIG. 4B, in accordance with some embodiments.

FIG. 5A is a cross-sectional view illustrating a chip package structure, in accordance with some embodiments.

FIG. 5B is an enlarged cross-sectional view illustrating a bonding portion of the chip package structure of FIG. 5A, in accordance with some embodiments.

FIG. 5B-1 is an enlarged cross-sectional view of a first portion of the chip package structure of FIG. 5B, in accordance with some embodiments.

FIG. 5B-2 is an enlarged cross-sectional view of a second portion of the chip package structure of FIG. 5B, in accordance with some embodiments.

FIG. 5C is a top view of the bonding pads and the conductive vias of FIG. 5B, in accordance with some embodiments.

FIG. 6A is a cross-sectional view illustrating a bonding portion of a chip package structure, in accordance with some embodiments.

FIG. 6B is a top view of the bonding pads and the conductive vias of FIG. 6A, in accordance with some embodiments.

FIG. 7A is a cross-sectional view illustrating a bonding portion of a chip package structure, in accordance with some embodiments.

FIG. 7B is a top view of the bonding pads and the conductive vias of FIG. 7A, in accordance with some embodiments.

FIG. 8A is a cross-sectional view illustrating a bonding portion of a chip package structure, in accordance with some embodiments.

FIG. 8B is an enlarged cross-sectional view illustrating a region of the bonding portion of FIG. 8A, in accordance with some embodiments.

FIG. 9 is a cross-sectional view illustrating a bonding portion of a chip package structure, in accordance with some embodiments.

FIG. 10A is a cross-sectional view illustrating a bonding portion of a chip package structure, in accordance with some embodiments.

FIG. 10B is an enlarged cross-sectional view illustrating a first portion of the chip package structure of FIG. 10A, in accordance with some embodiments.

FIG. 10C is an enlarged cross-sectional view illustrating a second portion of the chip package structure of FIG. 10A, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art.

For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x+5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

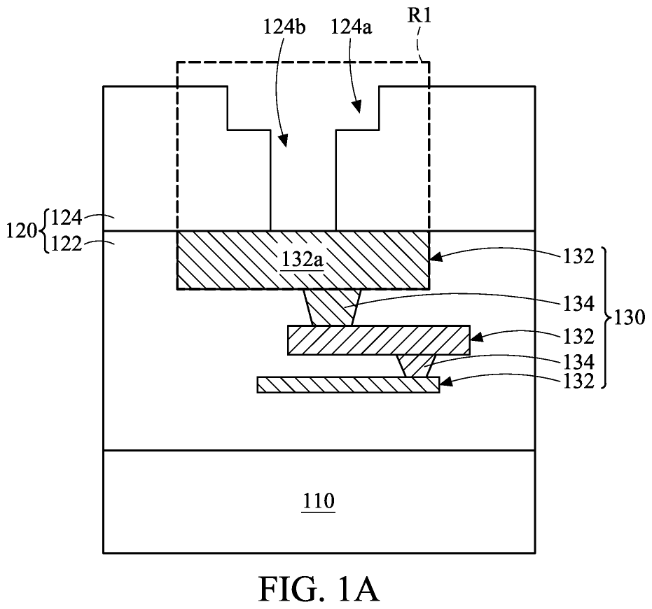

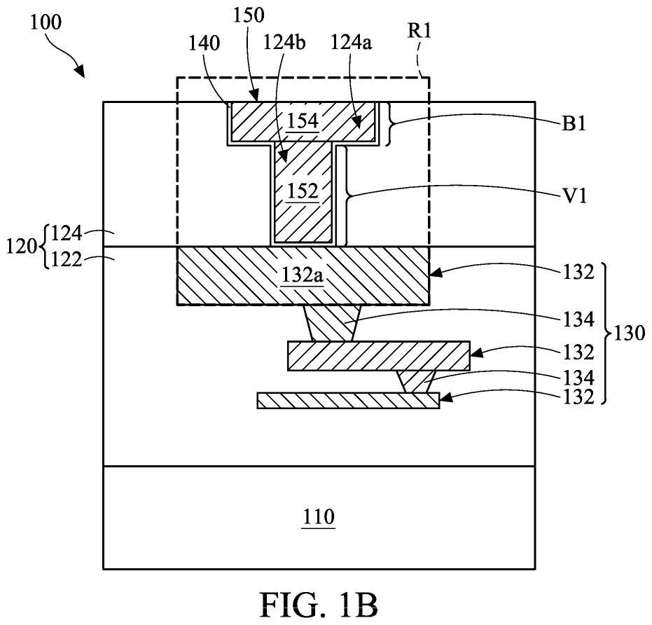

FIGS. 1A-1B are cross-sectional views of various stages of a process for forming a semiconductor structure, in accordance with some embodiments. As shown in FIG. 1A, a substrate 110 is provided, in accordance with some embodiments. The substrate 110 includes, for example, a semiconductor substrate. The substrate 110 includes, for example, a semiconductor wafer (such as a silicon wafer) or a portion of a semiconductor wafer.

In some embodiments, the substrate 110 is made of an elementary semiconductor material including silicon or germanium in a single crystal structure, a polycrystal structure, or an amorphous structure. In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements. In some embodiments, the various device elements are formed in and/or over the substrate 110. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

As shown in FIG. 1A, a dielectric structure 120 and an interconnect structure 130 are formed over the substrate 110, in accordance with some embodiments. The dielectric structure 120 includes dielectric layers 122 and 124, in accordance with some embodiments. The dielectric layer 124 is formed over the dielectric layer 122, in accordance with some embodiments. The interconnect structure 130 is formed in the dielectric layer 122, in accordance with some embodiments.

The interconnect structure 130 includes wiring layers 132 and conductive vias 134, in accordance with some embodiments. The conductive vias 134 are connected between the wiring layers 132 and between the wiring layers 132 and the device elements formed in and/or over the substrate 110, in accordance with some embodiments.

Each wiring layer 132 includes conductive lines 132a, in accordance with some embodiments. The dielectric layer 124 has a trench 124a and a through hole 124b, in accordance with some embodiments. The through hole 124b is under and connected to the trench 124a, in accordance with some embodiments. The through hole 124b and the trench 124a expose a portion of the conductive line 132a thereunder, in accordance with some embodiments.

The dielectric structure 120 is made of silicon oxide, silicon oxynitride, borosilicate glass (BSG), phosphoric silicate glass (PSG), borophosphosilicate glass (BPSG), fluorinated silicate glass (FSG), a low-k material, a porous dielectric material, or a combination thereof, in accordance with some embodiments.

The interconnect structure 130 is made of conductive materials such as metal (e.g., aluminum, copper or tungsten) or alloys thereof, in accordance with some embodiments.

As shown in FIG. 1B, a conductive via structure V1 and a bonding pad B1 are respectively formed in the through hole 124b and the trench 124a, in accordance with some embodiments. The conductive via structure V1 and the bonding pad B1 are embedded in the dielectric layer 124, in accordance with some embodiments. The conductive via structure V1 is connected between the bonding pad B1 and the conductive line 132a thereunder, in accordance with some embodiments.

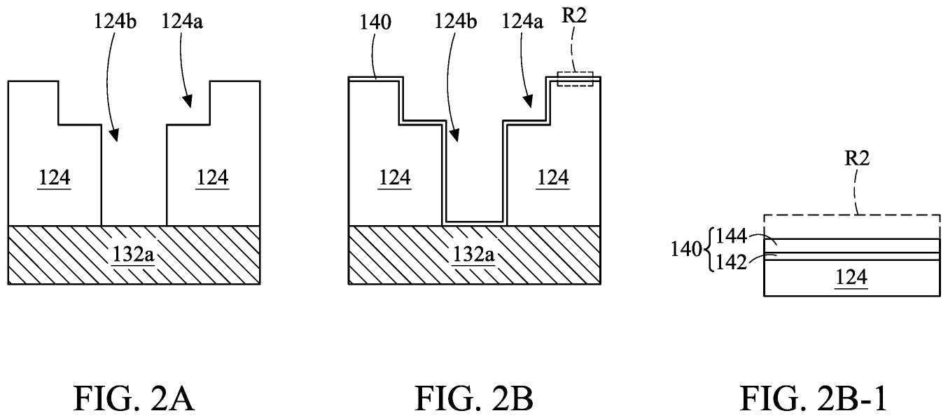

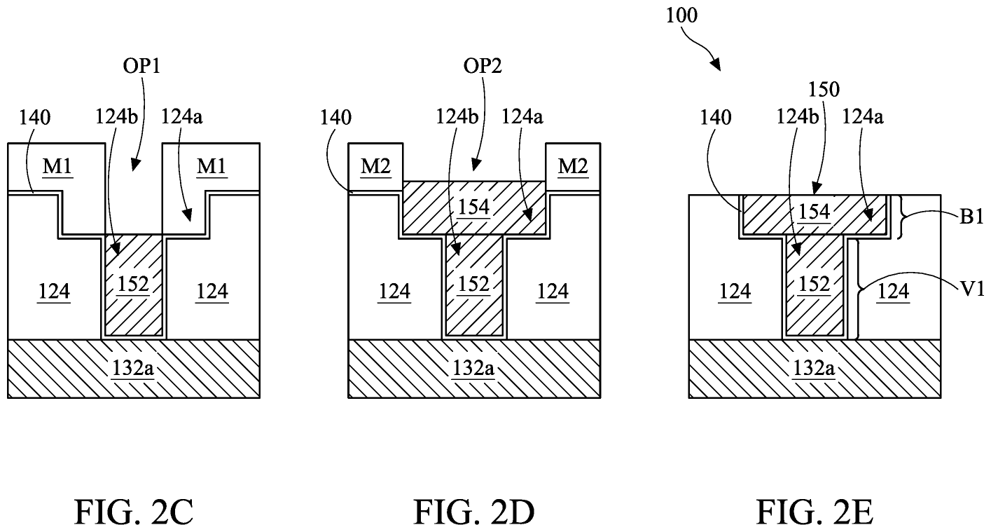

The method for forming the conductive via structure V1 and the bonding pad B1 is illustrated in FIGS. 2A-2E, in accordance with some embodiments. FIGS. 2A-2E are enlarged cross-sectional views of various stages of a process for forming the bonding pad B1 and the conductive via structure V1 of FIG. 1B, in accordance with some embodiments.

FIG. 2A is an enlarged cross-sectional view of the portion R1 of the semiconductor structure of FIG. 1A, in accordance with some embodiments. FIG. 2E is an enlarged cross-sectional view of the portion R1 of the semiconductor structure of FIG. 1B, in accordance with some embodiments.

After the step of FIGS. 1A and 2A, as shown in FIG. 2B, a seed layer 140 is formed over the dielectric layer 124 and the conductive line 132a, in accordance with some embodiments. FIG. 2B-1 is an enlarged cross-sectional view of a portion R2 of the semiconductor structure of FIG. 2B, in accordance with some embodiments.

As shown in FIGS. 2B and 2B-1, the seed layer 140 includes an adhesive film 142 and a conductive film 144, in accordance with some embodiments. The adhesive film 142 is formed over the dielectric layer 124 and the conductive line 132a, in accordance with some embodiments. The conductive film 144 is formed over the adhesive film 142, in accordance with some embodiments.

The adhesive film 142 is made of a first metal element, in accordance with some embodiments. The conductive film 144 is made of a second metal element and a third metal element, in accordance with some embodiments. The second metal element has a greater conductivity than the first metal element and the third metal element, in accordance with some embodiments. The third metal element reacts more readily with oxygen than the second metal element, in accordance with some embodiments.

The first metal element includes tantalum or titanium, in accordance with some embodiments. The second metal element includes copper, in accordance with some embodiments. The third metal element includes cobalt or manganese, in accordance with some embodiments. The conductive film 144 is made of an alloy material including copper and cobalt and/or manganese, in accordance with some embodiments. That is, the conductive film 144 is made of a Cu—Co alloy, a Cu—Mn alloy, or a Cu—Co—Mn alloy, in accordance with some embodiments.

The adhesive film 142 is formed using a deposition process such as an atomic layer deposition process and/or a physical vapor deposition process, in accordance with some embodiments. The conductive film 144 is formed using a deposition process such as a physical vapor deposition process, in accordance with some embodiments.

As shown in FIG. 2C, a mask layer M1 is formed over the seed layer 140, in accordance with some embodiments. The mask layer M1 has an opening OP1, in accordance with some embodiments. The opening OP1 exposes a portion of the seed layer 140 in the through hole 124b, in accordance with some embodiments. The mask layer M1 is made of a polymer material such as a photoresist material, in accordance with some embodiments.

As shown in FIG. 2C, a conductive layer 152 is formed over the exposed portion of the seed layer 140 in the through hole 124b, in accordance with some embodiments. The conductive layer 152 is made of a conductive material such as a metal material (e.g., copper or alloys thereof), in accordance with some embodiments. The conductive layer 152 is formed using a plating process such as an electroplating process, in accordance with some embodiments.

As shown in FIG. 2D, the mask layer M1 is removed, in accordance with some embodiments. As shown in FIG. 2D, a mask layer M2 is formed over the seed layer 140, in accordance with some embodiments. The mask layer M2 has an opening OP2, in accordance with some embodiments. The opening OP2 exposes a portion of the seed layer 140 in the trench 124a, in accordance with some embodiments. The mask layer M2 is made of a polymer material such as a photoresist material, in accordance with some embodiments.

As shown in FIG. 2D, a conductive layer 154 is formed over the conductive layer 152 and the exposed portion of the seed layer 140 in the trench 124a, in accordance with some embodiments. The conductive layer 154 is made of a conductive material such as a metal material (e.g., copper or alloys thereof), in accordance with some embodiments. The conductive layer 154 is formed using a plating process such as an electroplating process, in accordance with some embodiments.

As shown in FIGS. 1B and 2E, the mask layer M2 is removed, in accordance with some embodiments. As shown in FIG. 2E, top portions of the seed layer 140 and the conductive layer 154 outside of the trench 124a and the through hole 124b are removed, in accordance with some embodiments.

The seed layer 140 in the through hole 124b and the conductive layer 152 together form the conductive via structure V1, in accordance with some embodiments. The seed layer 140 in the trench 124a and the conductive layer 154 together form the bonding pad B1, in accordance with some embodiments. The conductive layers 152 and 154 together form a conductive structure 150, in accordance with some embodiments.

The removal process includes a planarization process such as a chemical mechanical polishing process, in accordance with some embodiments. In this step, a wiring substrate 100 is substantially formed, in accordance with some embodiments.

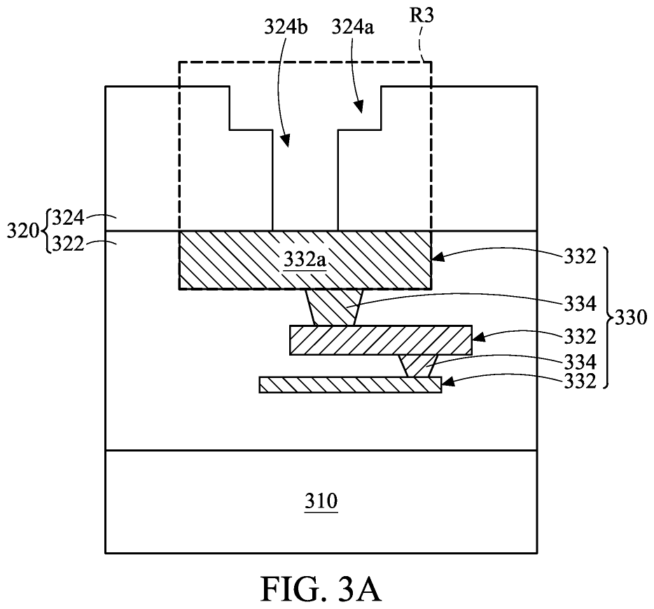

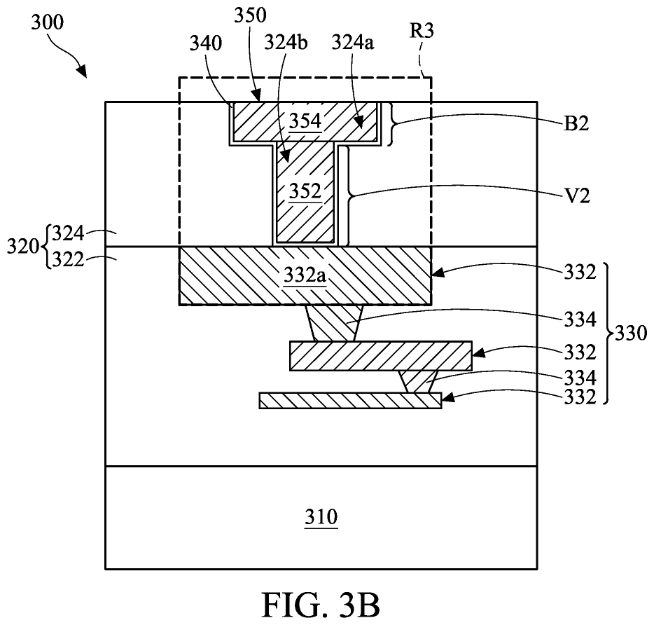

FIGS. 3A-3B are cross-sectional views of various stages of a process for forming a semiconductor structure, in accordance with some embodiments. As shown in FIG. 3A, a substrate 310 is provided, in accordance with some embodiments. The substrate 310 includes, for example, a semiconductor substrate. The substrate 310 includes, for example, a semiconductor wafer (such as a silicon wafer) or a portion of a semiconductor wafer.

In some embodiments, the substrate 310 is made of an elementary semiconductor material including silicon or germanium in a single crystal structure, a polycrystal structure, or an amorphous structure. In some other embodiments, the substrate 310 is made of a compound semiconductor, such as silicon carbide, gallium arsenide, gallium phosphide, indium phosphide, indium arsenide, an alloy semiconductor, such as SiGe or GaAsP, or a combination thereof. The substrate 310 may also include multi-layer semiconductors, semiconductor on insulator (SOI) (such as silicon on insulator or germanium on insulator), or a combination thereof.

In some embodiments, the substrate 310 is a device wafer that includes various device elements. In some embodiments, the various device elements are formed in and/or over the substrate 310. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate 310. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 310. The isolation features are used to surround active regions and electrically isolate various device elements formed in and/or over the substrate 310 in the active regions. In some embodiments, the isolation features include shallow trench isolation (STI) features, local oxidation of silicon (LOCOS) features, other suitable isolation features, or a combination thereof.

As shown in FIG. 3A, a dielectric structure 320 and an interconnect structure 330 are formed over the substrate 310, in accordance with some embodiments. The dielectric structure 320 includes dielectric layers 322 and 324, in accordance with some embodiments. The dielectric layer 324 is formed over the dielectric layer 322, in accordance with some embodiments. The interconnect structure 330 is formed in the dielectric layer 322, in accordance with some embodiments.

The interconnect structure 330 includes wiring layers 332 and conductive vias 334, in accordance with some embodiments. The conductive vias 334 are connected between the wiring layers 332 and between the wiring layers 332 and the device elements formed in and/or over the substrate 310, in accordance with some embodiments.

Each wiring layer 332 includes conductive lines 332a, in accordance with some embodiments. The dielectric layer 324 has a trench 324a and a through hole 324b, in accordance with some embodiments. The through hole 324b is under and connected to the trench 324a, in accordance with some embodiments. The through hole 324b and the trench 324a expose a portion of the conductive line 332a thereunder, in accordance with some embodiments.

The dielectric structure 320 is made of silicon oxide, silicon oxynitride, borosilicate glass (BSG), phosphoric silicate glass (PSG), borophosphosilicate glass (BPSG), fluorinated silicate glass (FSG), a low-k material, a porous dielectric material, or a combination thereof, in accordance with some embodiments.

The interconnect structure 330 is made of conductive materials such as metal (e.g., aluminum, copper or tungsten) or alloys thereof, in accordance with some embodiments.

As shown in FIG. 3B, a conductive via structure V2 and a bonding pad B2 are respectively formed in the through hole 324b and the trench 324a, in accordance with some embodiments. The conductive via structure V2 and the bonding pad B2 are embedded in the dielectric layer 324, in accordance with some embodiments. The conductive via structure V2 is connected between the bonding pad B2 and the conductive line 332a thereunder, in accordance with some embodiments.

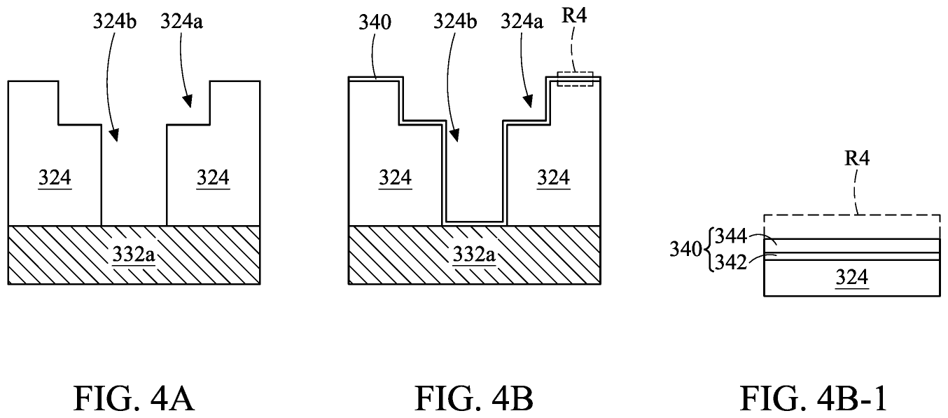

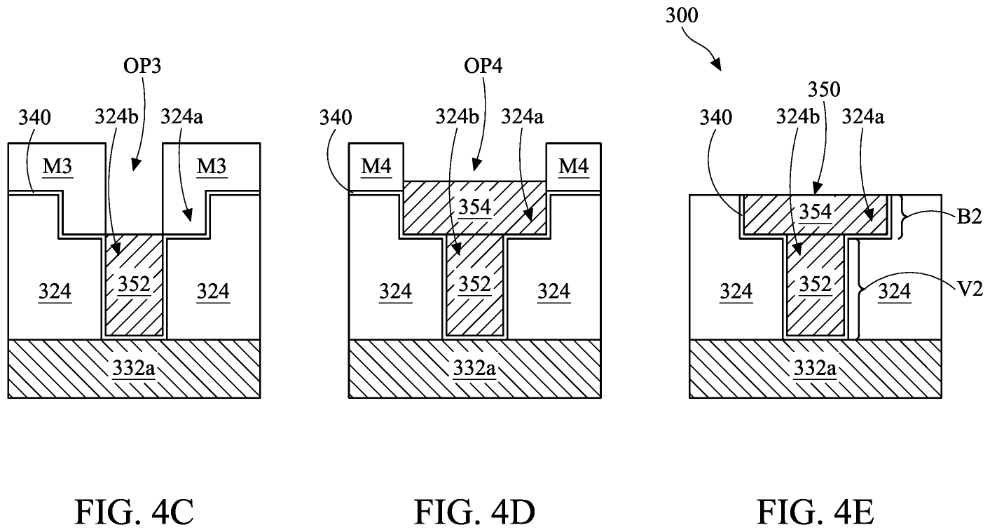

The method for forming the conductive via structure V2 and the bonding pad B2 is illustrated in FIGS. 4A-4E, in accordance with some embodiments. FIGS. 4A-4E are enlarged cross-sectional views of various stages of a process for forming the bonding pad B2 and the conductive via structure V2 of FIG. 3B, in accordance with some embodiments.

FIG. 4A is an enlarged cross-sectional view of the portion R3 of the semiconductor structure of FIG. 3A, in accordance with some embodiments. FIG. 4E is an enlarged cross-sectional view of the portion R3 of the semiconductor structure of FIG. 3B, in accordance with some embodiments.

After the step of FIGS. 3A and 4A, as shown in FIG. 4B, a seed layer 340 is formed over the dielectric layer 324 and the conductive line 332a, in accordance with some embodiments. FIG. 4B-1 is an enlarged cross-sectional view of a portion R4 of the semiconductor structure of FIG. 4B, in accordance with some embodiments.

As shown in FIGS. 4B and 4B-1, the seed layer 340 includes an adhesive film 342 and a conductive film 344, in accordance with some embodiments. The adhesive film 342 is formed over the dielectric layer 324 and the conductive line 332a, in accordance with some embodiments. The conductive film 344 is formed over the adhesive film 342, in accordance with some embodiments.

The adhesive film 342 is made of a first metal element, in accordance with some embodiments. The conductive film 344 is made of a second metal element and a third metal element, in accordance with some embodiments. The second metal element has a greater conductivity than the first metal element and the third metal element, in accordance with some embodiments. The third metal element reacts more readily with oxygen than the second metal element, in accordance with some embodiments.

The first metal element includes tantalum or titanium, in accordance with some embodiments. The second metal element includes copper, in accordance with some embodiments. The third metal element includes cobalt or manganese, in accordance with some embodiments. The conductive film 344 is made of an alloy material including copper and cobalt and/or manganese, in accordance with some embodiments. That is, the conductive film 344 is made of a Cu—Co alloy, a Cu—Mn alloy, or a Cu—Co—Mn alloy, in accordance with some embodiments.

The adhesive film 342 is formed using a deposition process such as an atomic layer deposition process and/or a physical vapor deposition process, in accordance with some embodiments. The conductive film 344 is formed using a deposition process such as a physical vapor deposition process, in accordance with some embodiments.

As shown in FIG. 4C, a mask layer M3 is formed over the seed layer 340, in accordance with some embodiments. The mask layer M3 has an opening OP3, in accordance with some embodiments. The opening OP3 exposes a portion of the seed layer 340 in the through hole 324b, in accordance with some embodiments. The mask layer M3 is made of a polymer material such as a photoresist material, in accordance with some embodiments.

As shown in FIG. 4C, a conductive layer 352 is formed over the exposed portion of the seed layer 340 in the through hole 324b, in accordance with some embodiments. The conductive layer 352 is made of a conductive material such as a metal material (e.g., copper or alloys thereof), in accordance with some embodiments. The conductive layer 352 is formed using a plating process such as an electroplating process, in accordance with some embodiments.

As shown in FIG. 4D, the mask layer M3 is removed, in accordance with some embodiments. As shown in FIG. 4D, a mask layer M4 is formed over the seed layer 340, in accordance with some embodiments. The mask layer M4 has an opening OP4, in accordance with some embodiments. The opening OP4 exposes a portion of the seed layer 340 in the trench 324a, in accordance with some embodiments. The mask layer M4 is made of a polymer material such as a photoresist material, in accordance with some embodiments.

As shown in FIG. 4D, a conductive layer 354 is formed over the conductive layer 352 and the exposed portion of the seed layer 340 in the trench 324a, in accordance with some embodiments. The conductive layer 354 is made of a conductive material such as a metal material (e.g., copper or alloys thereof), in accordance with some embodiments. The conductive layer 354 is formed using a plating process such as an electroplating process, in accordance with some embodiments.

As shown in FIGS. 3B and 4E, the mask layer M4 is removed, in accordance with some embodiments. As shown in FIG. 4E, top portions of the seed layer 340 and the conductive layer 354 outside of the trench 324a and the through hole 324b are removed, in accordance with some embodiments.

The seed layer 340 in the through hole 324b and the conductive layer 352 together form the conductive via structure V2, in accordance with some embodiments. The seed layer 340 in the trench 324a and the conductive layer 354 together form the bonding pad B2, in accordance with some embodiments. The conductive layers 352 and 354 together form a conductive structure 350, in accordance with some embodiments.

The removal process includes a planarization process such as a chemical mechanical polishing process, in accordance with some embodiments. In this step, a wiring substrate 300 is substantially formed, in accordance with some embodiments.

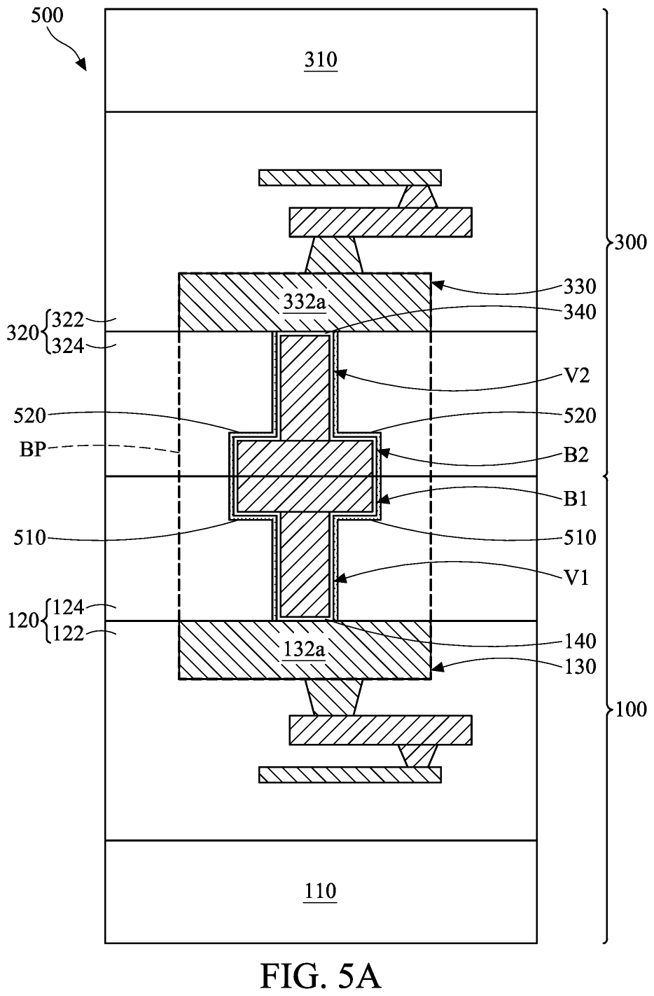

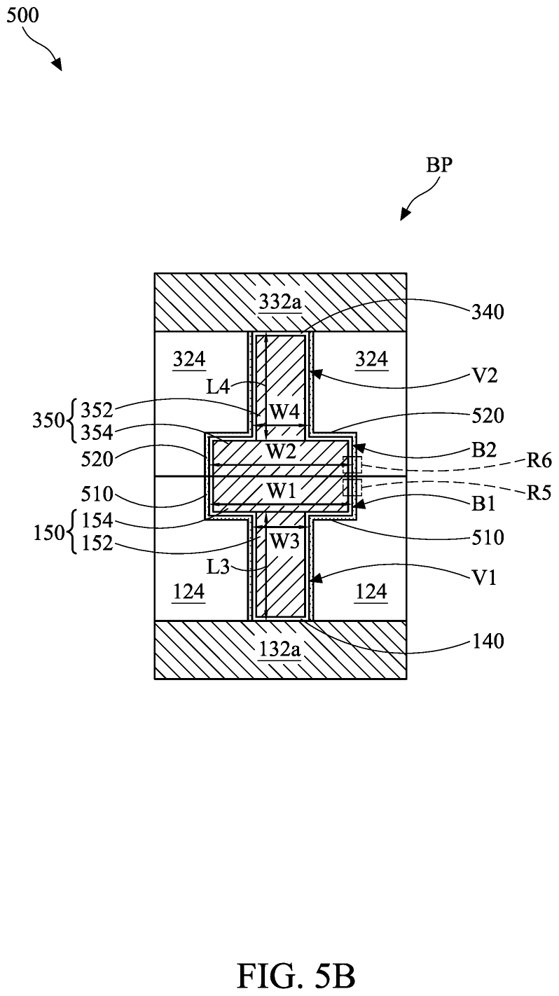

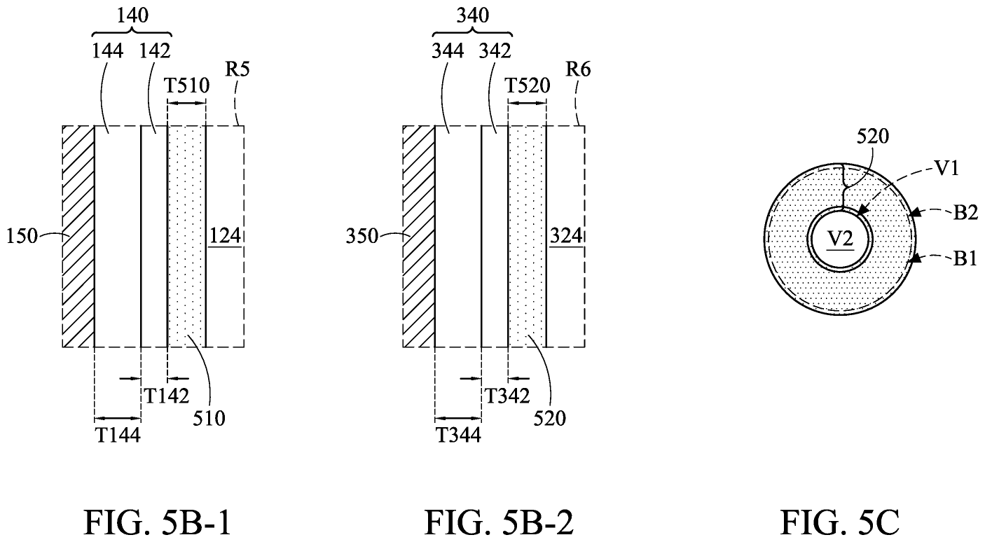

FIG. 5A is a cross-sectional view illustrating a chip package structure, in accordance with some embodiments. FIG. 5B is an enlarged cross-sectional view illustrating a bonding portion BP of the chip package structure of FIG. 5A, in accordance with some embodiments.

After the steps of FIGS. 1B and 3B are performed, as shown in FIGS. 5A and 5B, the wiring substrate 300 of FIG. 3B is flipped upside down and disposed over the wiring substrate 100 of FIG. 1B, in accordance with some embodiments. The bonding pad B2 is over the bonding pad B1, in accordance with some embodiments. The dielectric layer 324 is over the dielectric layer 124, in accordance with some embodiments.

Thereafter, as shown in FIGS. 5A and 5B, an annealing process is performed to bond the bonding pad B2 to the bonding pad B1 and to bond the dielectric layer 324 to the dielectric layer 124, in accordance with some embodiments.

After the annealing process, as shown in FIGS. 5A and 5B, a metal oxide layer 510 is formed between the seed layer 140 and the dielectric layer 124, and a metal oxide layer 520 is formed between the seed layer 340 and the dielectric layer 324, in accordance with some embodiments. The annealing temperature ranges from about 200 degree C. to about 300 degree C., in accordance with some embodiments. In this step, a chip package structure 500 is substantially formed, in accordance with some embodiments.

FIG. 5B-1 is an enlarged cross-sectional view of a first portion R5 of the chip package structure 500 of FIG. 5B, in accordance with some embodiments. As shown in FIGS. 5B and 5B-1, the metal oxide layer 510 is formed between the adhesive film 142 and the dielectric layer 124, in accordance with some embodiments. The metal oxide layer 510 is in direct contact with the adhesive film 142 and the dielectric layer 124, in accordance with some embodiments.

The metal oxide layer 510 includes the first metal element from the adhesive film 142 and the third metal element from the conductive film 144, in accordance with some embodiments. The first metal element includes tantalum or titanium, in accordance with some embodiments. The third metal element includes cobalt or manganese, in accordance with some embodiments. The metal oxide layer 510 is made of TaₓCo_{y}O_{1-x-y}, TaₓMn_{y}O_{1-x-y}, TiₓCo_{y}O_{1-x-y}, or TiₓMn_{y}O_{1-x-y}, wherein 0≤x<1 and 0<y<1, in accordance with some embodiments.

As shown in FIG. 5B-1, the metal oxide layer 510 is thinner than the conductive film 144, in accordance with some embodiments. That is, the thickness T510 of the metal oxide layer 510 is less than the thickness T144 of the conductive film 144, in accordance with some embodiments. If the conductive film 144 is thinner than the metal oxide layer 510, the conductive film 144 is too thin, which adversely affects the formation of the conductive structure 150, in accordance with some embodiments. The metal oxide layer 510 is thicker than the adhesive film 142, in accordance with some embodiments. That is, the thickness T510 of the metal oxide layer 510 is greater than the thickness T142 of the adhesive film 142, in accordance with some embodiments. The thickness T144 of the conductive film 144 is greater than the thickness T142 of the adhesive film 142, in accordance with some embodiments.

In some embodiments, the metal oxide layer 510 is thinner than the seed layer 140. In some other embodiments, the metal oxide layer 510 and the seed layer 140 have substantially the same thickness.

In some embodiments, a density of the metal oxide layer 510 is greater than a density of the seed layer 140. Therefore, the metal oxide layer 510 can prevent oxygen atoms of the dielectric layer 124 from diffusing into the conductive structure 150, thereby preventing the conductive structure 150 from being oxidized, in accordance with some embodiments. Furthermore, the metal oxide layer 510 can prevent copper atoms of the conductive structure 150 from diffusing into the dielectric layer 124, thereby preventing the conductive structure 150 from shorting, in accordance with some embodiments. Therefore, the performance and the reliability of the chip package structure 500 are improved, in accordance with some embodiments.

FIG. 5B-2 is an enlarged cross-sectional view of a second portion R6 of the chip package structure 500 of FIG. 5B, in accordance with some embodiments. As shown in FIGS. 5B and 5B-2, the metal oxide layer 520 is formed between the adhesive film 342 and the dielectric layer 324, in accordance with some embodiments. The metal oxide layer 520 is in direct contact with the adhesive film 342 and the dielectric layer 324, in accordance with some embodiments.

The metal oxide layer 520 includes the first metal element from the adhesive film 342 and the third metal element from the conductive film 344, in accordance with some embodiments. The first metal element includes tantalum or titanium, in accordance with some embodiments. The third metal element includes cobalt or manganese, in accordance with some embodiments. The metal oxide layer 520 is made of TaₓCo_{y}O_{1-x-y}, TaₓMn_{y}O_{1-x-y}, TiₓCo_{y}O_{1-x-y}, or TiₓMn_{y}O_{1-x-y}, wherein 0≤x<1 and 0<y<1, in accordance with some embodiments.

As shown in FIG. 5B-2, the metal oxide layer 520 is thinner than the conductive film 344, in accordance with some embodiments. That is, the thickness T520 of the metal oxide layer 520 is less than the thickness T344 of the conductive film 344, in accordance with some embodiments. The metal oxide layer 520 is thicker than the adhesive film 342, in accordance with some embodiments. That is, the thickness T520 of the metal oxide layer 520 is greater than the thickness T342 of the adhesive film 342, in accordance with some embodiments. The thickness T344 of the conductive film 344 is greater than the thickness T342 of the adhesive film 342, in accordance with some embodiments.

In some embodiments, a density of the metal oxide layer 520 is greater than a density of the seed layer 340. Therefore, the metal oxide layer 520 can prevent oxygen atoms of the dielectric layer 324 from diffusing into the conductive structure 350, thereby preventing the conductive structure 350 from being oxidized, in accordance with some embodiments.

Furthermore, the metal oxide layer 520 can prevent copper atoms of the conductive structure 350 from diffusing into the dielectric layer 324, thereby preventing the conductive structure 350 from shorting, in accordance with some embodiments. Therefore, the performance and the reliability of the chip package structure 500 are improved, in accordance with some embodiments.

FIG. 5C is a top view of the bonding pads B1 and B2 and the conductive vias V1 and V2 of FIG. 5B, in accordance with some embodiments. As shown in FIGS. 5B and 5C, the bonding pads B1 and B2 are aligned with each other, in accordance with some embodiments.

The metal oxide layer 510 is in direct contact with the metal oxide layer 520, in accordance with some embodiments. The seed layer 140 is in direct contact with the seed layer 340, in accordance with some embodiments. The width W1 of the bonding pad B1 is substantially equal to the width W2 of the bonding pad B2, in accordance with some embodiments.

In some embodiments, the width W3 of the conductive via V1 is substantially equal to the width W4 of the conductive via V2. In some embodiments, the width W3 of the conductive via V1 is greater than the width W4 of the conductive via V2. In some embodiments, the width W3 of the conductive via V1 is less than the width W4 of the conductive via V2.

In some embodiments, the length L3 of the conductive via V1 is substantially equal to the length L4 of the conductive via V2. In some embodiments, the length L3 of the conductive via V1 is greater than the length L4 of the conductive via V2. In some embodiments, the length L3 of the conductive via V1 is less than the length L4 of the conductive via V2.

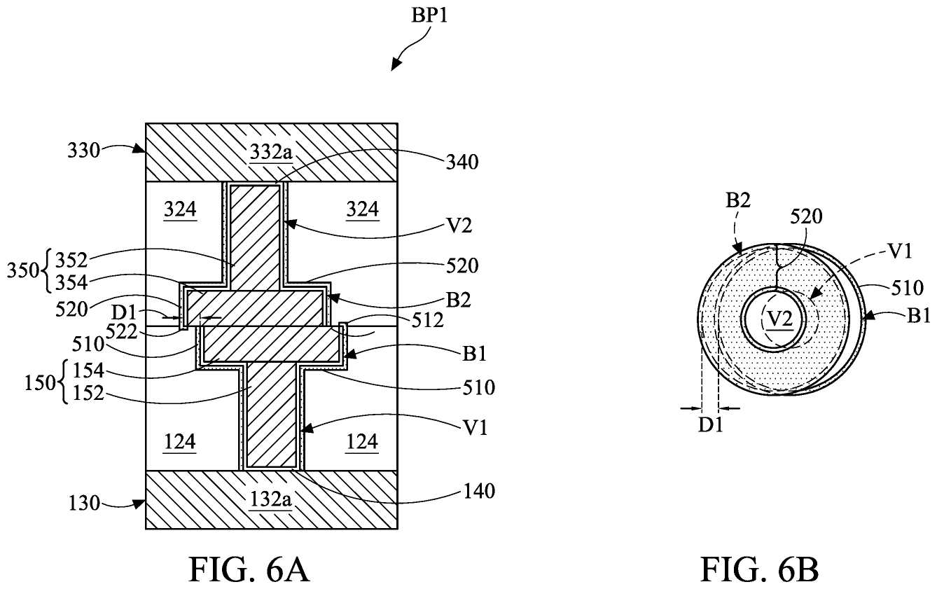

FIG. 6A is a cross-sectional view illustrating a bonding portion BP1 of a chip package structure, in accordance with some embodiments. FIG. 6B is a top view of the bonding pads B1 and B2 and the conductive vias V1 and V2 of FIG. 6A, in accordance with some embodiments.

As shown in FIGS. 6A and 6B, the bonding portion BP1 of FIG. 6A is similar to the bonding portion BP of FIG. 5B, except that the bonding pad B1 is misaligned with the bonding pad B2 of FIG. 6A, in accordance with some embodiments. The shift distance D1 between the bonding pads B1 and B2 ranges from about 0.01 μm to 1.5 μm, in accordance with some embodiments.

The metal oxide layer 510 is in direct contact with the dielectric layer 324, in accordance with some embodiments. The metal oxide layer 510 is in direct contact with the bonding pad B2, in accordance with some embodiments. In some embodiments, a portion 512 of the metal oxide layer 510 is between the seed layer 140 and the dielectric layer 324. The portion 512 of the metal oxide layer 510 extends into the dielectric layer 324, in accordance with some embodiments.

The metal oxide layer 520 is in direct contact with the dielectric layer 124, in accordance with some embodiments. The metal oxide layer 520 is in direct contact with the bonding pad B1, in accordance with some embodiments. In some embodiments, a portion 522 of the metal oxide layer 520 is between the seed layer 340 and the dielectric layer 124. The portion 522 of the metal oxide layer 520 extends into the dielectric layer 124, in accordance with some embodiments.

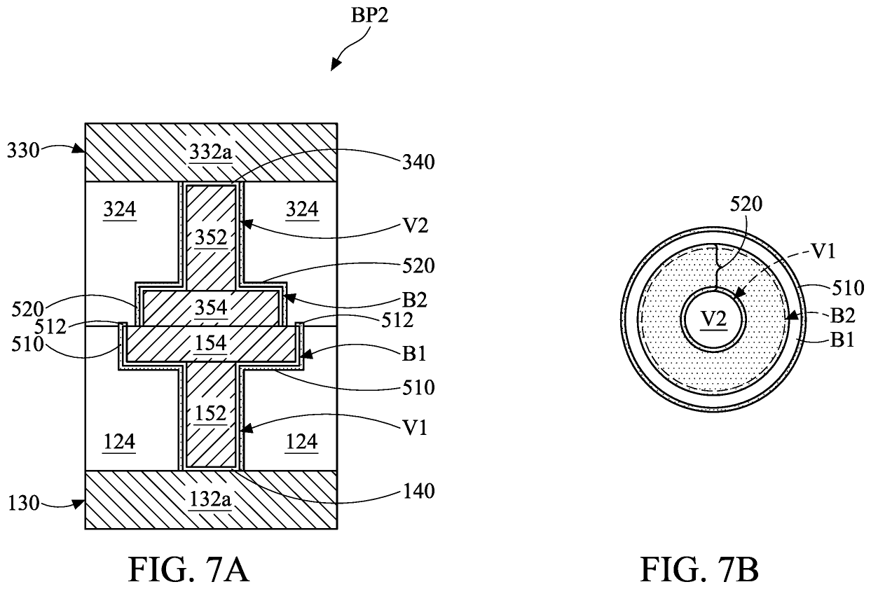

FIG. 7A is a cross-sectional view illustrating a bonding portion BP2 of a chip package structure, in accordance with some embodiments. FIG. 7B is a top view of the bonding pads B1 and B2 and the conductive vias V1 and V2 of FIG. 7A, in accordance with some embodiments.

As shown in FIGS. 7A and 7B, the bonding portion BP2 of FIG. 7A is similar to the bonding portion BP of FIG. 5B, except that the bonding pad B1 is wider than the bonding pad B2 of FIG. 7A, in accordance with some embodiments.

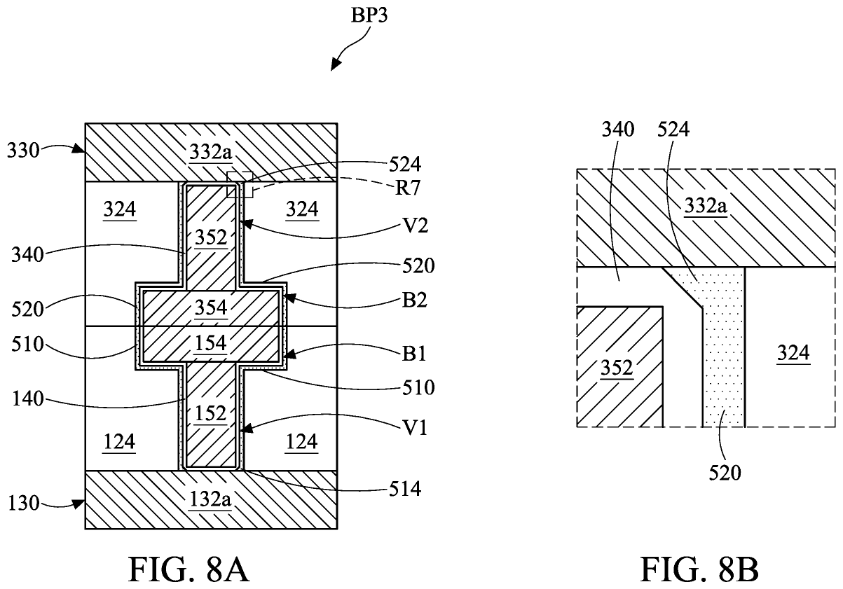

FIG. 8A is a cross-sectional view illustrating a bonding portion BP3 of a chip package structure, in accordance with some embodiments. FIG. 8B is an enlarged cross-sectional view illustrating a region R7 of the bonding portion BP3 of FIG. 8A, in accordance with some embodiments.

As shown in FIGS. 8A and 8B, the bonding portion BP3 of FIG. 8A is similar to the bonding portion BP of FIG. 5B, except that the metal oxide layer 510 has a portion 514 between the conductive via structure V1 and the conductive line 132a, and the metal oxide layer 520 has a portion 524 between the conductive via structure V2 and the conductive line 332a of FIG. 8A, in accordance with some embodiments.

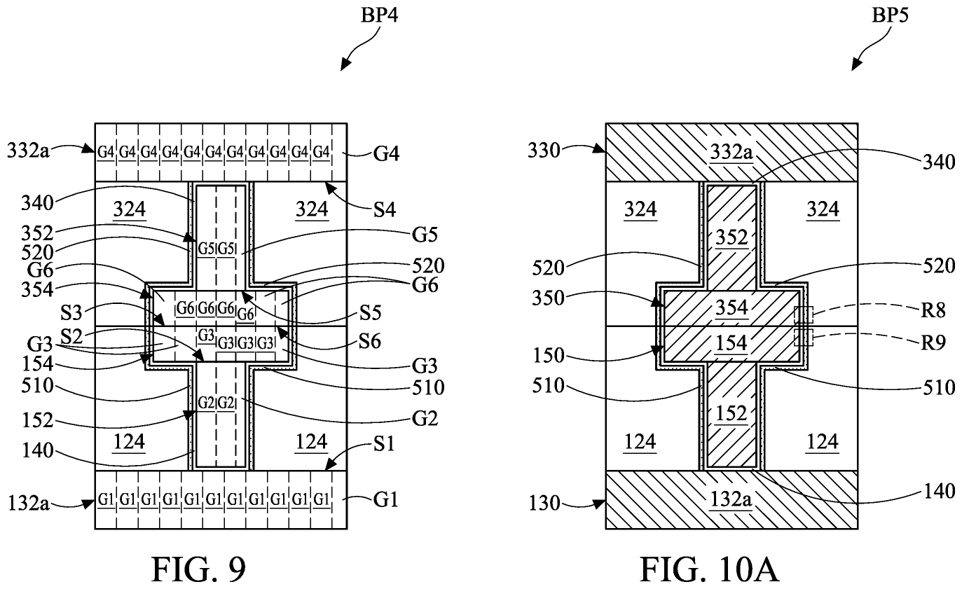

FIG. 9 is a cross-sectional view illustrating a bonding portion BP4 of a chip package structure, in accordance with some embodiments. As shown in FIG. 9, the bonding portion BP4 of FIG. 9 is similar to the bonding portion BP of FIG. 5B, except that the conductive lines 132a and 332a and the conductive layers 152, 154, 352, and 354 have texture structures with a (111) plane, in accordance with some embodiments.

The conductive line 132a has pillar grains G1, in accordance with some embodiments. The pillar grains G1 has a (111) plane S1, in accordance with some embodiments. The conductive layer 152 has pillar grains G2, in accordance with some embodiments.

The pillar grains G2 has a (111) plane S2, in accordance with some embodiments. The conductive layer 154 has pillar grains G3, in accordance with some embodiments. The pillar grains G3 has a (111) plane S3, in accordance with some embodiments.

The conductive line 332a has pillar grains G4, in accordance with some embodiments. The pillar grains G4 has a (111) plane S4, in accordance with some embodiments. The conductive layer 352 has pillar grains G5, in accordance with some embodiments.

The pillar grains G5 has a (111) plane S5, in accordance with some embodiments. The conductive layer 354 has pillar grains G6, in accordance with some embodiments. The pillar grains G6 has a (111) plane S6, in accordance with some embodiments.

The diffusion speed of copper atoms on the (111) plane is high, which improves the bonding between the conductive line 132a, the conductive layers 152 and 154, the conductive layer 354 and 352, and the conductive line 332a, in accordance with some embodiments.

Furthermore, the annealing process for bonding the bonding pad B1 to the bonding pad B2 can use a lower annealing temperature, in accordance with some embodiments. For example, the annealing temperature ranges from about 150 degree C. to about 300 degree C., in accordance with some embodiments. The annealing temperature ranges from about 150 degree C. to about 200 degree C., in accordance with some embodiments.

The conductive line 132a, the conductive layers 152 and 154, the conductive layer 354 and 352, and the conductive line 332a are formed using electroplating processes using direct current voltage and pulse voltage, in accordance with some embodiments.

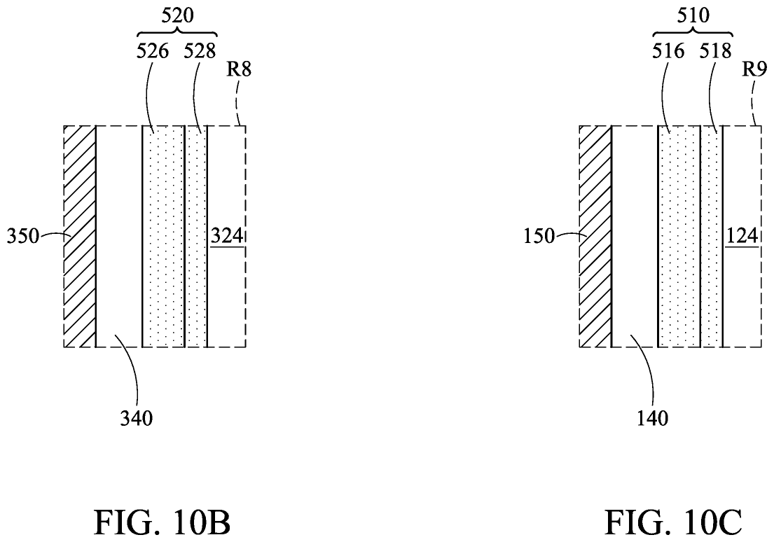

FIG. 10A is a cross-sectional view illustrating a bonding portion BP5 of a chip package structure, in accordance with some embodiments. FIG. 10B is an enlarged cross-sectional view illustrating a first portion R8 of the chip package structure of FIG. 10A, in accordance with some embodiments. FIG. 10C is an enlarged cross-sectional view illustrating a second portion R9 of the chip package structure of FIG. 10A, in accordance with some embodiments.

As shown in FIGS. 10A, 10B and 10C, the bonding portion BP5 of FIG. 10A is similar to the bonding portion BP of FIG. 5B, except that the metal oxide layer 510 includes films 516 and 518, and the metal oxide layer 520 includes films 526 and 528, in accordance with some embodiments.

As shown in FIGS. 10A and 10C, the seed layer 140 includes cobalt and manganese, in accordance with some embodiments. The film 516 is between the seed layer 140 and the film 518, in accordance with some embodiments. The film 516 has a higher cobalt concentration than the film 518, in accordance with some embodiments. The film 518 has a higher manganese concentration than the film 516, in accordance with some embodiments.

The film 516 is made of TaₓCo_{y}O_{1-x-y} or TiₓCo_{y}O_{1-x-y}, wherein 0≤x<1 and 0<y<1, in accordance with some embodiments. The film 518 is made of TaₓMn_{y}O_{1-x-y} or TiₓMn_{y}O_{1-x-y}, wherein 0≤x<1 and 0<y<1, in accordance with some embodiments.

As shown in FIGS. 10A and 10C, the seed layer 340 includes cobalt and manganese, in accordance with some embodiments. The film 526 is between the seed layer 340 and the film 528, in accordance with some embodiments. The film 526 has a higher cobalt concentration than the film 528, in accordance with some embodiments. The film 528 has a higher manganese concentration than the film 526, in accordance with some embodiments.

Processes and materials for forming the bonding portions BP1, BP2, BP3, BP4 and BP5 may be similar to, or the same as, those for forming the bonding portion BP described above. Elements designated by the same or similar reference numbers as those in FIGS. 1A to 10C have the same or similar structures and the materials. Therefore, the detailed descriptions thereof will not be repeated herein.

In accordance with some embodiments, chip package structures and methods for forming the same are provided. The methods (for forming the chip package structure) form a seed layer in a first bonding pad embedded in a dielectric layer. The seed layer includes a metal element, which reacts more readily with oxygen than copper. Therefore, after the first bonding pad is bonded to a second bonding pad using an annealing process, a metal oxide layer is formed between the seed layer and the dielectric layer. The metal oxide layer can prevent oxygen atoms of the dielectric layer from diffusing into the first bonding pad, thereby preventing the first bonding pad from being oxidized. Furthermore, the metal oxide layer can prevent copper atoms of the first bonding pad from diffusing into the dielectric layer, thereby preventing the first bonding pad from shorting. Therefore, the performance and the reliability of the chip package structures are improved.

In accordance with some embodiments, a method for forming a chip package structure is provided. The method includes providing a first wiring substrate including a first dielectric layer and a first bonding pad embedded in the first dielectric layer. The first bonding pad includes a conductive layer and a seed layer between the conductive layer and the first dielectric layer, the seed layer includes an adhesive film and a conductive film, the adhesive film is made of a first metal element, the conductive film is made of a second metal element and a third metal element, the second metal element has a greater conductivity than the first metal element and the third metal element, and the third metal element reacts more readily with oxygen than the second metal element. The method includes providing a second wiring substrate over the first wiring substrate. The second wiring substrate includes a second dielectric layer and a second bonding pad embedded in the second dielectric layer, and the second bonding pad is over the first bonding pad. The method includes performing an annealing process to bond the second bonding pad to the first bonding pad, wherein a metal oxide layer is formed between the seed layer and the first dielectric layer after the annealing process, and the metal oxide layer includes the first metal element and the third metal element.

In accordance with some embodiments, a method for forming a chip package structure is provided. The method includes providing a first wiring substrate including a first dielectric layer and a first bonding pad embedded in the first dielectric layer. The first bonding pad includes a conductive layer and a seed layer between the conductive layer and the first dielectric layer. The method includes providing a second wiring substrate over the first wiring substrate. The second wiring substrate includes a second dielectric layer and a second bonding pad embedded in the second dielectric layer, and the second bonding pad is over the first bonding pad. The method includes bonding the second bonding pad to the first bonding pad using an annealing process, wherein a metal oxide layer is formed between the seed layer and the first dielectric layer after the annealing process, and a first density of the metal oxide layer is greater than a second density of the seed layer.

In accordance with some embodiments, a chip package structure is provided. The chip package structure includes a first wiring substrate including a first dielectric layer, a first bonding pad, and a first metal oxide layer. The first bonding pad is embedded in the first dielectric layer, the first metal oxide layer is between the first bonding pad and the first dielectric layer. The first bonding pad includes a conductive layer and a seed layer between the conductive layer and the first dielectric layer, the seed layer includes an adhesive film and a conductive film, the adhesive film is made of a first metal element, the conductive film is made of a second metal element and a third metal element, the second metal element has a greater conductivity than the first metal element and the third metal element, the third metal element reacts more readily with oxygen than the second metal element, and the first metal oxide layer includes the first metal element and the third metal element. The chip package structure includes a second wiring substrate bonded to the first wiring substrate. The second wiring substrate includes a second dielectric layer and a second bonding pad embedded in the second dielectric layer, and the second bonding pad is bonded to the first bonding pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a chip package structure, comprising:
providing a first wiring substrate comprising a first dielectric layer and a first bonding pad embedded in the first dielectric layer, wherein the first bonding pad comprises a conductive layer and a seed layer between the conductive layer and the first dielectric layer, the seed layer comprises an adhesive film and a conductive film, the adhesive film comprises a first metal element, the conductive film comprises a second metal element and a third metal element, the second metal element has a greater conductivity than the first metal element and the third metal element, and the third metal element reacts more readily with oxygen than the second metal element;
providing a second wiring substrate over the first wiring substrate, wherein the second wiring substrate comprises a second dielectric layer and a second bonding pad embedded in the second dielectric layer; and
performing an annealing process to bond the second bonding pad to the first bonding pad, wherein a metal oxide layer is formed between the seed layer and the first dielectric layer after the annealing process, and the metal oxide layer comprises the first metal element and the third metal element.

2. The method for forming the chip package structure as claimed in claim 1, wherein the third metal element comprises cobalt or manganese.

3. The method for forming the chip package structure as claimed in claim 1, wherein the first metal element comprises tantalum or titanium.

4. The method for forming the chip package structure as claimed in claim 1, wherein the second metal element comprises copper.

5. The method for forming the chip package structure as claimed in claim 1, wherein the metal oxide layer is thinner than the conductive film.

6. The method for forming the chip package structure as claimed in claim 5, wherein the metal oxide layer is thicker than the adhesive film.

7. The method for forming the chip package structure as claimed in claim 1, wherein a portion of the metal oxide layer is between the seed layer and the second dielectric layer.

8. The method for forming the chip package structure as claimed in claim 1, wherein the metal oxide layer is in direct contact with the adhesive film and the first dielectric layer.

9. The method for forming the chip package structure as claimed in claim 1, wherein the metal oxide layer is in direct contact with the second dielectric layer.

10. The method for forming the chip package structure as claimed in claim 9, wherein the metal oxide layer is in direct contact with the second bonding pad.

11. The method for forming the chip package structure as claimed in claim 1, further comprising:
bonding the first dielectric layer to the second dielectric layer during bonding the first bonding pad to the second bonding pad.

12. A method for forming a chip package structure, comprising:
providing a first wiring substrate comprising a first dielectric layer and a first bonding pad embedded in the first dielectric layer, wherein the first bonding pad comprises a conductive layer and a seed layer between the conductive layer and the first dielectric layer;
providing a second wiring substrate over the first wiring substrate, wherein the second wiring substrate comprises a second dielectric layer and a second bonding pad embedded in the second dielectric layer; and
bonding the second bonding pad to the first bonding pad using an annealing process, wherein a metal oxide layer is formed between the seed layer and the first dielectric layer after the annealing process, and a first density of the metal oxide layer is greater than a second density of the seed layer.

13. The method for forming the chip package structure as claimed in claim 12, wherein the seed layer comprises cobalt and manganese, the metal oxide layer comprises a first film and a second film, the first film is between the seed layer and the second film, and the first film has a higher cobalt concentration than the second film.

14. The method for forming the chip package structure as claimed in claim 13, wherein the second film has a higher manganese concentration than the first film.

15. The method for forming the chip package structure as claimed in claim 12, wherein the metal oxide layer extends into the second dielectric layer.

16. A chip package structure, comprising:
a first wiring substrate comprising a first dielectric layer, a first bonding pad embedded in the first dielectric layer, and a first metal oxide layer between the first bonding pad and the first dielectric layer,
the first bonding pad comprises a conductive layer and a seed layer between the conductive layer and the first dielectric layer, the seed layer comprises an adhesive film and a conductive film, the adhesive film comprises a first metal element, the conductive film is made of a second metal element and a third metal element, the second metal element has a greater conductivity than the first metal element and the third metal element, the third metal element reacts more readily with oxygen than the second metal element, and the first metal oxide layer comprises the first metal element and the third metal element; and
a second wiring substrate bonded to the first wiring substrate, wherein the second wiring substrate comprises a second dielectric layer and a second bonding pad embedded in the second dielectric layer, and the second bonding pad is bonded to the first bonding pad.

17. The chip package structure as claimed in claim 16, wherein the third metal element comprises cobalt or manganese.

18. The chip package structure as claimed in claim 16, wherein the second wiring substrate further comprises:
a second metal oxide layer between the second bonding pad and the second dielectric layer, wherein the second metal oxide layer comprises cobalt or manganese.

19. The chip package structure as claimed in claim 18, wherein the first metal oxide layer is in direct contact with the second metal oxide layer.

20. The chip package structure as claimed in claim 18, wherein the first wiring substrate further comprises a conductive line and a conductive via structure, the first dielectric layer is over the conductive line, the conductive via structure is in the first dielectric layer and connected between the conductive line and the first bonding pad, and a portion of the first metal oxide layer is between the conductive via structure and the conductive line.
